(19) United States
(12) Patent Application Publication
(10) Pub. No.: US 2018/0122980 A1
(43) Pub. Date: May 3, 2018

(54) SOLAR CELL AND SOLAR CELL MANUFACTURING METHOD

(71) Applicant: Mitsubishi Electric Corporation, Chiyoda-ku, Tokyo (JP)

(72) Inventors: Hiroaki MORIKAWA, Tokyo (JP); Atsuro HAMA, Tokyo (JP); Hayato KOHATA, Tokyo (JP); Shintaro KANO, Tokyo (JP)

(73) Assignee: Mitsubishi Electric Corporation, Chiyoda-ku, Tokyo (JP)

(21) Appl. No.: 15/566,371

(22) PCT Filed: Jul. 2, 2015
(86) PCT No.: PCT/JP2015/069174

§ 371 Date: Oct. 13, 2017

(51) Int. Cl. H01L 31/18; H01L 31/0224; H01L 31/0368

(52) U.S. Cl. CPC H01L 31/1868; H01L 31/03685; H01L 31/022425

(57) ABSTRACT

A solar cell includes a p-type impurity diffusion layer formed on one side of an n-type single-crystal silicon substrate, an n-type impurity diffusion layer formed on the opposite side of the substrate with an n-type impurity element at a higher concentration than the substrate, and having a first layer with an n-type impurity element diffused at a first concentration, and a second layer with an n-type impurity element diffused at a second concentration lower than the first concentration, on-p-type-impurity-diffusion-layer electrodes formed on the p-type impurity diffusion layer, and on-n-type-impurity-diffusion-layer electrodes formed on the first layer. The concentration of the n-type impurity element at a surface of the first layer is between 5×10²⁰ atoms/cm³ and 2×10²¹ atoms/cm³ inclusive, and the concentration of the n-type impurity element at a surface of the second layer is between 5×10¹⁹ atoms/cm³ and 2×10²⁰ atoms/cm³ inclusive.

### FIELD

The present invention relates to a solar cell using an n-type silicon substrate and a method for manufacturing the solar cell.

### BACKGROUND

A solar cell structure designed to increase the photoelectric conversion efficiency is known from Patent Literature 1. Such a structure has a p-type emitter layer on the light-receiving side of an n-type silicon substrate, and a back surface field (BSF) layer on the opposite side. The BSF layer has a region under the electrodes, the region being higher in impurity concentration than the other regions. This configuration can reduce contact resistance between the region under the electrodes and the respective electrodes. Further, in the regions other than the region under the electrodes, passivation effect can be obtained due to BSF effect.

### CITATION LIST

### Patent Literature

Patent Literature 1: Japanese Patent No. 5379767

### SUMMARY

### Technical Problem

For technique in Patent Literature 1 above, a lithography technique is used in forming the region under the electrodes that is higher in impurity concentration than the other regions. For this reason, unfortunately, the technique in Patent Literature 1 is disadvantageous in that the manufacturing process is complicated and the manufacturing cost is increased.

Further, in order to increase the photoelectric conversion efficiency, it is important to appropriately adjust the impurity concentration so as to effectively deliver passivation performance at the regions other than the region under the electrodes.

The present invention has been made in view of the above, and an object of the invention is to provide a solar cell that can be formed by a simple process at a low cost, and can be increased in photoelectric conversion efficiency.

### Solution to Problem

To solve the above problems and achieve the object, the present invention provides a solar cell comprising: an n-type silicon substrate; a p-type impurity diffusion layer formed on one side of the n-type silicon substrate and containing a p-type impurity element; an n-type impurity diffusion layer formed on an opposite side of the n-type silicon substrate and containing an n-type impurity element at a higher concentration than the n-type silicon substrate, the n-type impurity diffusion layer having a first n-type impurity diffusion layer in which an n-type impurity element is diffused at a first concentration, and a second n-type impurity diffusion layer in which an n-type impurity element is diffused at a second concentration lower than the first concentration; on-p-type-impurity-diffusion-layer electrodes formed on the p-type impurity diffusion layer; and on-n-type-impurity-diffusion-layer electrodes formed on the first n-type impurity diffusion layer, wherein a concentration of the n-type impurity element at a surface of the first n-type impurity diffusion layer is between 5×10²⁰ atoms/cm³ and 2×10²¹ atoms/cm³ inclusive, and a concentration of the n-type impurity element at a surface of the second n-type impurity diffusion layer is between 5×10¹⁹ atoms/cm³ and 2×10²⁰ atoms/cm³ inclusive.

### Advantageous Effects of Invention

The solar cell according to the present invention achieves the effect that a solar cell that can be formed by a simple process at a low cost and can be increased in photoelectric conversion efficiency.

### BRIEF DESCRIPTION OF DRAWINGS

FIG. 1 is a plan view as viewed from the light-receiving side of a solar cell according to a first embodiment of the present invention.

FIG. 2 is a plan view as viewed from the back side opposite to a light-receiving surface of the solar cell according to the first embodiment of the present invention.

FIG. 3 is a cross-sectional view of a major part illustrating the configuration of the solar cell according to the first embodiment of the present invention, the cross-sectional view being taken along line A-A in FIG. 1.

FIG. 4 is a flowchart for explaining an example of a solar cell manufacturing method according to the first embodiment of the present invention.

FIG. 5 is a cross-sectional view of the major part for explaining the example of the solar cell manufacturing method according to the first embodiment of the present invention.

FIG. 6 is a cross-sectional view of the major part for explaining the example of the solar cell manufacturing method according to the first embodiment of the present invention.

FIG. 7 is a cross-sectional view of the major part for explaining the example of the solar cell manufacturing method according to the first embodiment of the present invention.

FIG. 8 is a cross-sectional view of the major part for explaining the example of the solar cell manufacturing method according to the first embodiment of the present invention.

FIG. 9 is a cross-sectional view of the major part for explaining the example of the solar cell manufacturing method according to the first embodiment of the present invention.

FIG. 10 is a cross-sectional view of the major part for explaining the example of the solar cell manufacturing method according to the first embodiment of the present invention.

FIG. 11 is a cross-sectional view of the major part for explaining the example of the solar cell manufacturing method according to the first embodiment of the present invention.

FIG. 12 is a cross-sectional view of the major part for explaining the example of the solar cell manufacturing method according to the first embodiment of the present invention.

FIG. 13 is a cross-sectional view of the major part for explaining the example of the solar cell manufacturing method according to the first embodiment of the present invention.

FIG. 14 is a cross-sectional view of the major part for explaining the example of the solar cell manufacturing method according to the first embodiment of the present invention.

FIG. 15 is a cross-sectional view of the major part for explaining the example of the solar cell manufacturing method according to the first embodiment of the present invention.

FIG. 16 is a characteristic diagram illustrating the relationship between the sheet resistance of a second n-type impurity diffusion layer and Implied-Voc at the completion of step 11 in solar cell samples produced according to the solar cell manufacturing method according to the first embodiment.

FIG. 17 is a cross-sectional view of a major part illustrating the configuration of a solar cell according to a second embodiment of the present invention.

### DESCRIPTION OF EMBODIMENTS

Hereinafter, a solar cell and a solar cell manufacturing method according to embodiments of the present invention will be described in detail with reference to the drawings. The embodiments are not intended to limit the invention. In the drawings described below, the scale of members may be different from an actual scale for the sake of easy understanding. The same applies to the scale between the drawings.

### First Embodiment

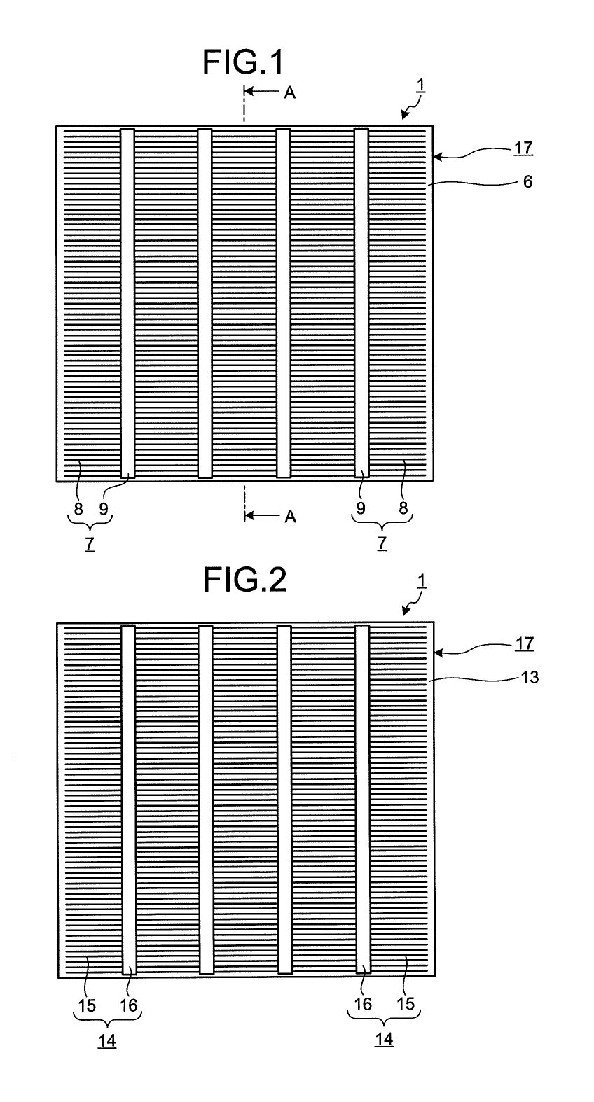

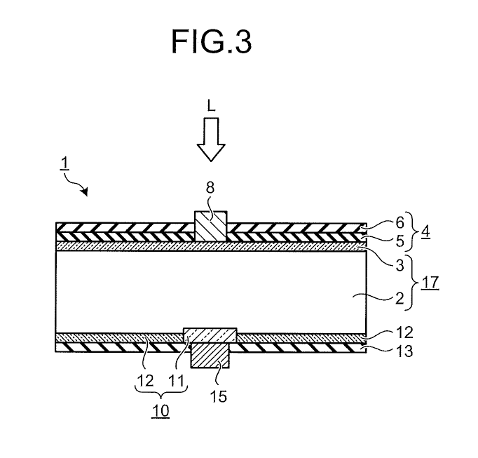

FIG. 1 is a plan view as viewed from the light-receiving side of a solar cell 1 according to a first embodiment of the present invention. FIG. 2 is a plan view as viewed from the back side opposite to a light-receiving surface of the solar cell 1 according to the first embodiment of the present invention. FIG. 3 is a cross-sectional view of a major part illustrating the configuration of the solar cell 1 according to the first embodiment of the present invention, the cross-sectional view being taken along line A-A in FIG. 1.

The solar cell 1 is a crystalline solar cell having a square external shape in the planar direction. The solar cell 1 includes a semiconductor substrate 17 including a semiconductor substrate 2 made of n-type single-crystal silicon having an external dimension of 156 mm×156 mm, that is, a square shape of 156 mm per side. On a light-receiving side of the semiconductor substrate 2, a p-type impurity diffusion layer 3 is formed by the diffusion of boron, which is a p-type impurity element, to thereby provide the semiconductor substrate 17 with a p-n junction. The semiconductor substrate 2 may be hereinafter referred to as an n-type single-crystal silicon substrate 2. On the p-type impurity diffusion layer 3, an on-p-type-impurity-diffusion-layer passivation film 4 made of insulating films is formed. The on-p-type-impurity-diffusion-layer passivation film 4 is hereinafter referred to as an on-p-type-layer passivation film 4. For the semiconductor substrate 2, an n-type polycrystalline silicon substrate may be used.

N-type silicon substrates having specifications of specific resistance in the range between about 0.5 Ωcm and 10 Ωcm inclusive are available for use in the manufacturing of solar cells. Sheet resistance mentioned about an n-type impurity diffusion layer in the first embodiment represents a sheet resistance value of only a first n-type impurity diffusion layer 11 or a second n-type impurity diffusion layer 12. In general, when an n-type impurity diffusion layer is formed on an n-type silicon substrate by diffusion of an n-type impurity, it is difficult to measure the sheet resistance of only the n-type impurity diffusion layer because current flows also between the n-type silicon substrate and the n-type impurity diffusion layer. To measure the sheet resistance of only the n-type impurity diffusion layer, a sheet resistance value of the n-type impurity diffusion layer obtained when the n-type impurity diffusion layer is formed on a p-type silicon substrate by thermal diffusion may be used. When the n-type impurity diffusion layer is formed on the p-type silicon substrate, the p-n junction prevents current from flowing between the p-type silicon substrate and the n-type impurity diffusion layer. Thus, measuring the sheet resistance of the n-type impurity diffusion layer by a measurement method such as a four-terminal method from the surface of the n-type impurity diffusion layer enables measuring the sheet resistance of only the n-type impurity diffusion layer. An n-type impurity element is hereinafter referred to simply as an n-type impurity.

Although not shown, microscopic asperities constituting a texture structure for confining light are formed on the light-receiving side of the n-type single-crystal silicon substrate 2. The microscopic asperities are structured such that the light-receiving surface has an increased area for absorbing light from the outside and a reduced reflectivity, thereby efficiently confining light in the solar cell 1. The microscopic asperities are pyramid-shaped asperities of a side of between about 0.1 μm and 10 μm inclusive, for example.

The on-p-type-layer passivation film 4 is an insulating film having translucency. The on-p-type-layer passivation film 4 is defined by an aluminum oxide (Al₂O₃) film 5 of a thickness of 5 nm and a silicon nitride (SiN) film 6 of a refractive index of 2.1 and a thickness of 80 nm. The film 5 and the film 6 are formed sequentially on the p-type impurity diffusion layer 3. The on-p-type-layer passivation film 4 is not limited to these films, and may be formed by an insulating film such as a silicon oxide (SiO₂) film or an titanium oxide (TiO₂) film. For the solar cell 1, light L enters from the on-p-type-layer passivation film 4 side.

Further, on the light-receiving side of the semiconductor substrate 17, a plurality of elongated on-p-type-impurity-diffusion-layer grid electrodes 8 is provided side by side, and on-p-type-impurity-diffusion-layer bus electrodes 9 electrically continuous with the on-p-type-impurity-diffusion-layer grid electrodes 8 are provided at right angles to the on-p-type-impurity-diffusion-layer grid electrodes 8. The on-p-type-impurity-diffusion-layer grid electrode 8 is hereinafter referred to as an on-p-type-layer grid electrode 8. The on-p-type-impurity-diffusion-layer bus electrode 9 is hereinafter referred to as an on-p-type-layer bus electrode 9. The on-p-type-layer grid electrodes 8 and the on-p-type-layer bus electrodes 9 are electrically connected to the p-type impurity diffusion layer 3 at their respective bottom surfaces. The on-p-type-layer grid electrodes 8 and the on-p-type-layer bus electrodes 9 are formed from a silver material.

The on-p-type-layer grid electrode 8 has a width of between about 40 μm and 70 μm inclusive, for example. The number of the on-p-type-layer grid electrodes 8 is between 100 and 300 inclusive. The on-p-type-layer grid electrodes 8 are arranged in parallel at fixed intervals and collect electricity generated in the semiconductor substrate 17. The on-p-type-layer bus electrode 9 has a width of between about 0.5 mm and 1.0 mm inclusive, for example. The number of the on-p-type-layer bus electrodes 9 disposed per solar cell is between three and five inclusive. The on-p-type-layer bus electrodes 9 take out electricity collected by the on-p-type-layer grid electrodes 8 to the outside. The on-p-type-layer grid electrodes 8 and the on-p-type-layer bus electrode 9 constitute an on-p-type-impurity-diffusion-layer electrode 7 as a light-receiving-side electrode having a comb shape.

The on-p-type-impurity-diffusion-layer electrode 7 is hereinafter referred to as an on-p-type-layer electrode 7. In the first embodiment, the number of the on-p-type-layer grid electrodes 8 is one hundred, the number of the on-p-type-layer bus electrodes 9 is four, the electrode width of the on-p-type-layer grid electrode 8 is 50 μm, and the electrode width of the on-p-type-layer bus electrode 9 is 1.0 mm. It should be noted that the number of the on-p-type-layer grid electrodes 8 in FIG. 1 is reduced for convenience of illustration.

An AgAl-containing paste, which is an electrode material paste containing silver (Ag) and aluminum (Al) with lead boron glass added thereto as a glass component are used as the electrode material of the on-p-type-layer electrode 7. This glass, which is fritted, is composed of, for example, lead (Pb) of between 5 wt % and 30 wt % inclusive, boron (B) of between 5 wt % and 10 wt % inclusive, silicon (Si) of between 5 wt % and 15 wt % inclusive, and oxygen (0) of between 30 wt % and 60 wt % inclusive. Further, an element such as zinc (Zn) or cadmium (Cd) may be mixed with the above composition by about several wt %. Such lead boron glass has the property of melting by heating at about 800° C. and then eroding silicon. Generally, A method of manufacturing crystalline silicon solar cells uses this property of glass frit to obtain an electrical contact between a silicon substrate and an electrode material paste.

The semiconductor substrate 17 has a surface layer portion located on the back side thereof opposite to the light-receiving surface. Formed in this surface layer portion of the semiconductor substrate 17 is an n-type impurity diffusion layer 10 that is an BSF layer, i.e., an n+layer containing a higher concentration of an n-type impurity than the n-type single-crystal silicon substrate 2. The provision of the n-type impurity diffusion layer 10 provides BSF effect to increase the hole concentration of the semiconductor substrate 2 in an electric field of a band structure such that holes in the semiconductor substrate 2, which is the n-type layer, do not disappear due to the surface recombination.

In the solar cell 1 according to the first embodiment, two types of layers as the n-type impurity diffusion layer 10 are formed to form a selective impurity diffusion layer structure. That is, a first n-type impurity diffusion layer 11 and a second n-type impurity diffusion layer 12 are formed in the surface layer portion of the n-type single-crystal silicon substrate 2 located on the back side thereof. The first n-type impurity diffusion layer 11 is located at a region and vicinities of this region, the region being beneath the on-n-type-impurity-diffusion-layer electrodes 14 that are back-side electrodes. The second n-type impurity diffusion layer 12 is located at regions where the first n-type impurity diffusion layer 11 is not formed. The first n-type impurity diffusion layer 11 is a low-resistance diffusion layer, i.e., a high-concentration impurity diffusion layer of the n-type impurity diffusion layer 10 in which n-type impurities are uniformly diffused at a relatively high concentration. The second n-type impurity diffusion layer 12 is a high-resistance diffusion layer, i.e., a low-concentration impurity diffusion layer of the n-type impurity diffusion layer 10 in which n-type impurities are uniformly diffused at a relatively low concentration.

Where the impurity diffusion concentration of the first n-type impurity diffusion layer 11 is referred to as a first diffusion concentration, and the impurity diffusion concentration of the second n-type impurity diffusion layer 12 is referred to as a second diffusion concentration, the second diffusion concentration is lower than the first diffusion concentration. Where the sheet resistance value of the first n-type impurity diffusion layer 11 is referred to as a first sheet resistance value, and the sheet resistance value of the second n-type impurity diffusion layer 12 is referred to as a second sheet resistance value, the second sheet resistance value is higher than the first sheet resistance value.

The second n-type impurity diffusion layer 12, which is the low-concentration impurity diffusion layer, acts as the BSF layer to prevent the recombination at the back surface of the semiconductor substrate 17, thereby contributing to the achievement of a favorable open-circuit voltage of the solar cell 1. The first n-type impurity diffusion layer 11, which is the high-concentration impurity diffusion layer, reduces contact resistance with the on-n-type-impurity-diffusion-layer electrodes 14 that are the back-side electrodes, thereby contributing to the achievement of a favorable fill factor of the solar cell 1.

In the solar cell 1 according to the first embodiment configured as above, the first n-type impurity diffusion layer 11 of the relatively low sheet resistance is formed beneath the on-n-type-impurity-diffusion-layer electrodes 14 that are the back-side electrodes on the back side, such that the contact resistance between the n-type single-crystal silicon substrate 2 and the respective on-n-type-impurity-diffusion-layer electrodes 14 is reduced. The second n-type impurity diffusion layer 12 of the relatively low n-type impurity concentration is formed in the regions other than the first n-type impurity diffusion layer 11 on the back side of the solar cell 1, such that recombination velocity at which holes are generated and disappear is decreased. Thus, the solar cell 1 according to the first embodiment has the selective impurity diffusion layer structure formed of the first n-type impurity diffusion layer 11 and the second n-type impurity diffusion layer 12.

All over the back surface of the semiconductor substrate 17, a silicon nitride film is provided as an on-n-type-impurity-diffusion-layer passivation film 13 that is an insulating film. The on-n-type-impurity-diffusion-layer passivation film 13 is hereinafter referred to as an on-n-type-layer passivation film 13. The provision of the on-n-type-layer passivation film 13 on the back surface of the semiconductor substrate 17 can deactivate defects at the back surface of the n-type single-crystal silicon substrate 2. The on-n-type-layer passivation film 13 is not limited to the silicon nitride film, and an insulating film such as a silicon oxide film may be used.

On the back surface of the semiconductor substrate 17, a plurality of elongated on-n-type-impurity-diffusion-layer grid electrodes 15 is provided side by side, and on-n-type-impurity-diffusion-layer bus electrodes 16 electrically continuous with the on-n-type-impurity-diffusion-layer grid electrodes 15 are provided at right angles to the on-n-type-impurity-diffusion-layer grid electrodes 15. The on-n-type-impurity-diffusion-layer grid electrodes 15 and the on-n-type-impurity-diffusion-layer bus electrodes 16 are electrically connected to the first n-type impurity diffusion layer 11 described below at their respective bottom surfaces. The on-n-type-impurity-diffusion-layer grid electrodes 15 and the on-n-type-impurity-diffusion-layer bus electrodes 16 are formed from a silver-containing material. The on-n-type-impurity-diffusion-layer grid electrode 15 is hereinafter referred to as an on-n-type-layer grid electrode 15. The on-n-type-impurity-diffusion-layer bus electrode 16 is hereinafter referred to as an on-n-type-layer bus electrode 16.

The on-n-type-layer grid electrode 15 has a width of between about 40 μm and 70 μm inclusive, and the number of the on-n-type-layer grid electrodes 15 is between 100 and 300 inclusive, for example. The on-n-type-layer grid electrodes 15 are arranged in parallel at fixed intervals and collect electricity generated in the semiconductor substrate 17. The on-n-type-layer bus electrode 16 has a width of between about 0.5 mm and 1.5 mm inclusive, and the number of the on-n-type-layer bus electrodes 16 disposed per solar cell is between three and five inclusive, for example. The on-n-type-layer bus electrodes 16 take out electricity collected by the on-n-type-layer grid electrodes 15 to the outside. The on-n-type-layer grid electrode 15 and the on-n-type-layer bus electrode 16 constitute the on-n-type-impurity-diffusion-layer electrode 14 as the back-side electrode having a comb shape. The on-n-type-impurity-diffusion-layer electrode 14 is hereinafter referred to as an on-n-type-layer electrode 14. In the first embodiment, the number of the on-n-type-layer grid electrodes 15 is one hundred, the number of the on-n-type-layer bus electrodes 16 is four, the electrode width of the on-n-type-layer grid electrode 15 is 60 μm, and the electrode width of the on-n-type-layer bus electrode 16 is 1.0 mm. The above-described on-n-type-layer electrodes 14 are formed on the first n-type impurity diffusion layer 11. It should be noted that the number of the on-n-type-layer grid electrodes 15 in FIG. 2 is reduced for convenience of illustration.

An Ag-containing paste, which is an electrode material paste containing Ag and glass frit added thereto, is used as the electrode material of the on-n-type-layer electrode 14.

The present inventors have studied conditions for achieving a high photoelectric conversion efficiency in the solar cell 1 having a solar cell configuration that has the selective impurity diffusion layer structure in the BSF layer on the back as described above.

When the impurity concentration at the surface of the first n-type impurity diffusion layer 11 is too low, the contact resistance between the respective on-n-type-layer electrodes 14 and the first n-type impurity diffusion layer 11 becomes great, and hence the fill factor of the solar cell 1 decreases. When the impurity concentration at the surface of the first n-type impurity diffusion layer 11 is too high, the open-circuit voltage of the solar cell 1 decreases. The first n-type impurity diffusion layer 11 has a portion lying on the on-n-type-layer grid electrodes 15, and this portion provides an effect of reducing the contact resistance with the on-n-type-layer grid electrodes 15 and increasing the fill factor of the solar cell 1. On the other hand, Portions of the first n-type impurity diffusion layer 11, which do not lie on the on-n-type-layer grid electrodes 15, substantially constitute a light-receiving n-type layer, and thus are required to have the same function as that of the second n-type impurity diffusion layer 12, that is, a function as the BSF layer, of preventing recombination at the back surface of the semiconductor substrate 17. Unfortunately, it is difficult for the first n-type impurity diffusion layer 11 and the on-n-type-layer grid electrodes 15 to have the same size and be placed on each other from the standpoint of the manufacturing. In fact, thus, there exists the first n-type impurity diffusion layer 11 on which the on-n-type-layer grid electrodes 15 are not formed. The first n-type impurity diffusion layer 11 on which the on-n-type-layer grid electrodes 15 are not formed causes a decrease in the open-circuit voltage of the solar cell 1. For the above reason, the first n-type impurity diffusion layer 11 need not have an impurity concentration higher than or equal to an impurity concentration at which to maintain proper contact resistance between the first n-type impurity diffusion layer 11 and the respective on-n-type-layer grid electrodes 15 when only the contact resistance between the first n-type impurity diffusion layer 11 and the respective on-n-type-layer grid electrodes 15 is taken into consideration. Rather, the impurity concentration of the first n-type impurity diffusion layer 11 is preferably lower than the concentration at which to maintain the proper contact resistance with the on-n-type-layer grid electrodes 15.

When phosphorus concentration at the surface of the second n-type impurity diffusion layer 12 is too low, the BSF effect becomes insufficient. When phosphorus concentration at the surface of the second n-type impurity diffusion layer 12 is too high, the surface recombination of holes in the semiconductor substrate 2 at the surface of the second n-type impurity diffusion layer 12 increases, and the open-circuit voltage decreases.

To achieve a high photoelectric conversion efficiency in the solar cell 1, thus, there is a proper combination of a phosphorus concentration, which is an n-type impurity element concentration at the surface of the first n-type impurity diffusion layer 11 and a phosphorus concentration, which is an n-type impurity element concentration at the surface of the second n-type impurity diffusion layer 12. In the solar cell 1, to this end, the impurity concentration at the surface of the first n-type impurity diffusion layer 11 is set in the range between 5×10²⁰ atoms/cm³ and 2×10²¹ atoms/cm³ inclusive, and the phosphorus concentration at the surface of the second n-type impurity diffusion layer 12 is set in the range between 5×10¹⁹atoms/cm³ and 2×10²⁰ atoms/cm³ inclusive. This allows the solar cell 1 to achieve the high photoelectric conversion efficiency. The phosphorus concentration at the surface of the first n-type impurity diffusion layer 11 and the phosphorus concentration at the surface of the second n-type impurity diffusion layer 12 in the solar cell 1 can be measured by secondary ion mass spectrometry (SIMS).

When the phosphorus concentration, which is the n-type impurity element concentration at the surface of the second n-type impurity diffusion layer 12, is in the range between 5×10¹⁹ atoms/cm³ and 2×10²⁰ atoms/cm³ inclusive, and the phosphorus concentration, which is the n-type impurity element concentration at the surface of the first n-type impurity diffusion layer 11, is less than 5×10²⁰ atoms/cm³, the contact resistance between the respective on-n-type-layer electrodes 14 and the first n-type impurity diffusion layer 11 increases, and the fill factor of the solar cell 1 decreases.

When the phosphorus concentration at the surface of the second n-type impurity diffusion layer 12 is in the range between 5×10¹⁹ atoms/cm³ and 2×10²⁰ atoms/cm³ inclusive, and the phosphorus concentration at the surface of the first n-type impurity diffusion layer 11 is higher than 2×10²¹ atoms/cm³, the first n-type impurity diffusion layer 11 on which the on-n-type-layer grid electrodes 15 are not formed causes the decrease in the open-circuit voltage of the solar cell 1 as described above.

When the phosphorus concentration at the surface of the first n-type impurity diffusion layer 11 is in the range between 5×10²⁰ atoms/cm³ and 2×10²¹ atoms/cm³ inclusive, the lower limit of the phosphorus concentration at the surface of the second n-type impurity diffusion layer 12 is about 5×10¹⁹ atoms/cm³ from the standpoint of the manufacturing because a step of forming the second n-type impurity diffusion layer 12 uses vapor-phase diffusion, as described later. Even if the phosphorus concentration at the surface of the second n-type impurity diffusion layer 12 is less than 5×10¹⁹ atoms/cm³ and down to about 1×10¹⁸ atoms/cm³, the photoelectric conversion efficiency of the solar cell 1 is in theory maintained at about the same level of photoelectric conversion efficiency as that at 5×10¹⁹ atoms/cm³. When the phosphorus concentration at the surface of the second n-type impurity diffusion layer 12 is less than 1×10¹⁸ atoms/cm³, the BSF effect becomes insufficient. As a result, the reflection effect of holes in the semiconductor substrate 2 decreases, recombination in the semiconductor substrate 2 increases, and open-circuit voltage and short-circuit current decrease.

When the phosphorus concentration at the surface of the first n-type impurity diffusion layer 11 is in the range between 5×10²⁰ atoms/cm³ and 2×10²¹ atoms/cm³ inclusive, and the phosphorus concentration at the surface of the second n-type impurity diffusion layer 12 is higher than 2×10²⁰ atoms/cm³, the surface recombination at the surface of the second n-type impurity diffusion layer 12 increases, and open-circuit voltage decreases.

When the sheet resistance of the first n-type impurity diffusion layer 11 is too low, the open-circuit voltage of the solar cell 1 decreases. The first n-type impurity diffusion layer 11 has the portion lying on the on-n-type-layer grid electrodes 15, and this portion provides an effect of reducing the contact resistance with the on-n-type-layer grid electrodes 15 and increasing the fill factor of the solar cell 1. On the other hand, the portions of the first n-type impurity diffusion layer 11, which do not lie on the on-n-type-layer grid electrodes 15, substantially constitute a light-receiving n-type layer, and thus are required to have the same function as that of the second n-type impurity diffusion layer 12, that is, a function as the BSF layer, of preventing recombination at the back surface of the semiconductor substrate 17. Unfortunately, it is difficult for the first n-type impurity diffusion layer 11 and the on-n-type-layer grid electrodes 15 to have the same size and be placed on each other from the standpoint of manufacturing. In fact, thus, there exists the first n-type impurity diffusion layer 11 on which the on-n-type-layer grid electrodes 15 are not formed. The first n-type impurity diffusion layer 11 on which the on-n-type-layer grid electrodes 15 are not formed causes the decrease in the open-circuit voltage of the solar cell 1. For the above reason, the first n-type impurity diffusion layer 11 need not have a sheet resistance lower than a sheet resistance at which to maintain the proper contact resistance between the first n-type impurity diffusion layer 11 and the respective on-n-type-layer grid electrodes 15 when only the contact resistance between the first n-type impurity diffusion layer 11 and the respective on-n-type-layer grid electrodes 15 is taken into consideration. Rather, the sheet resistance of the first n-type impurity diffusion layer 11 is preferably higher than the sheet resistance at which to maintain the proper contact resistance with the on-n-type-layer grid electrodes 15. When the sheet resistance of the first n-type impurity diffusion layer 11 is too high, the contact resistance between the respective on-n-type-layer electrodes 14 and the first n-type impurity diffusion layer 11 becomes great, and the fill factor of the solar cell 1 decreases.

When the sheet resistance of the second n-type impurity diffusion layer 12 is too low, the surface recombination at the surface of the second n-type impurity diffusion layer 12 increases, and the open-circuit voltage decreases. The upper limit of the sheet resistance of the second n-type impurity diffusion layer 12 is about 500 Ω/sq. from the standpoint of the manufacturing because the step of forming the second n-type impurity diffusion layer 12 uses the vapor-phase diffusion, as described later. Even if the sheet resistance of the second n-type impurity diffusion layer 12 is 500 Ω/sq. or higher and up to about 1000 Ω/sq., the photoelectric conversion efficiency of the solar cell 1 is in theory maintained at about the same level of photoelectric conversion efficiency as that at 500 Ω/sq. To achieve the high photoelectric conversion efficiency in the solar cell 1, thus, there is a proper combination of the sheet resistance of the first n-type impurity diffusion layer 11 and the sheet resistance of the second n-type impurity diffusion layer 12.

To this end, the sheet resistance of the first n-type impurity diffusion layer 11 is set in the range between 20 Ω/sq. and 80 Ω/sq. inclusive, and the sheet resistance of the second n-type impurity diffusion layer 12 is set greater than 150 Ω/sq. This allows the solar cell 1 to achieve the high photoelectric conversion efficiency. The upper limit of the sheet resistance of the second n-type impurity diffusion layer 12 is about 500 Ω/sq. from the standpoint of the manufacturing because the step of forming the second n-type impurity diffusion layer 12 uses the vapor-phase diffusion. Such a combination of ranges of the sheet resistance of the first n-type impurity diffusion layer 11 and the sheet resistance of the second n-type impurity diffusion layer 12 is achieved by the combination of the above-described range of the impurity concentration at the surface of the first n-type impurity diffusion layer 11 and the above-described range of the phosphorus concentration at the surface of the second n-type impurity diffusion layer 12.

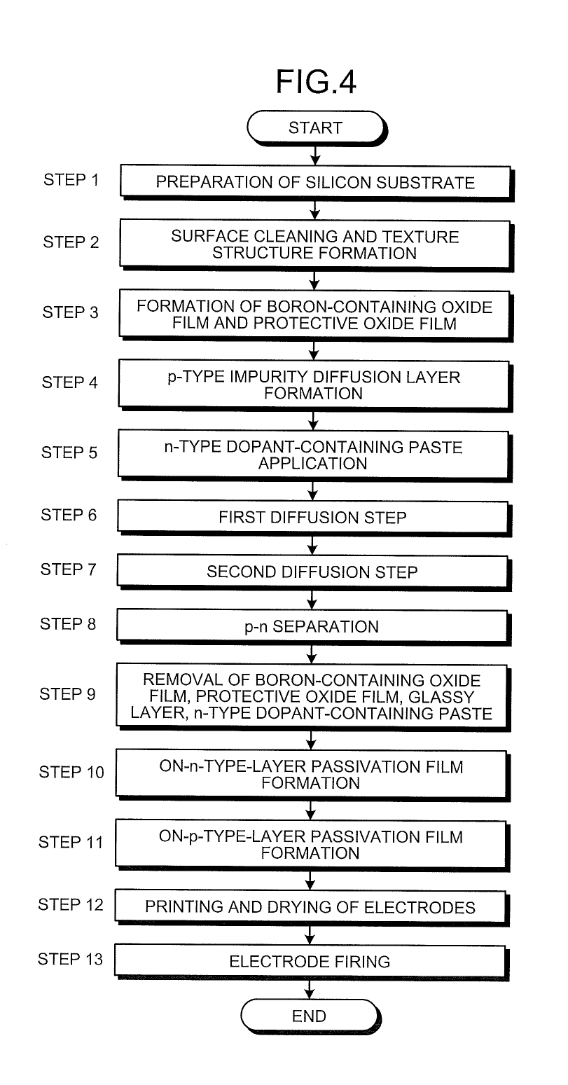

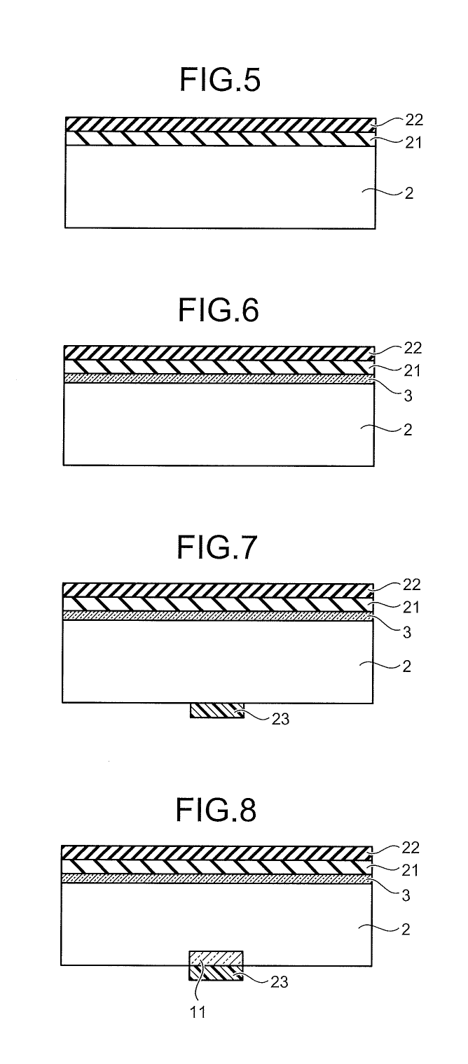

Next, a method of manufacturing the solar cell 1 according to the first embodiment will be described. FIG. 4 is a flowchart for explaining an example of the method of manufacturing the solar cell 1 according to the first embodiment of the present invention. FIGS. 5 to 15 are cross-sectional views of a major part for explaining the example of the method of manufacturing the solar cell 1 according to the first embodiment of the present invention. FIGS. 5 to 15 are cross-sectional views of the major part corresponding to FIG. 3.

(Silicon Substrate Preparation Step)

In step 1, the n-type single-crystal silicon substrate 2 is prepared as a semiconductor substrate. The n-type single-crystal silicon substrate 2 is manufactured by preparing a single-crystal silicon ingot formed by a method such as the Czochralski (CZ) method, and cutting and slicing the ingot to a desired external dimension and thickness using a cutting machine such as a band saw machine or a multi-wire saw machine. The diameter of the ingot is typically between 200 mm and 210 mm inclusive. Thus, the n-type single-crystal silicon substrate 2 of a thickness of about 180 μm, and an external dimension of 156 mm or more and 158 mm or less×156 mm or more and 158 mm or less in a square shape having round-chamfered square corners is obtained. The external shape of the n-type single-crystal silicon substrate 2 is cut out from a cylindrical ingot to be the square of 156 mm or more and 158 mm or less×156 mm or more and 158 mm or less with the four corners round-chamfered at R100 or more and R105 or less of a circle. The length of the diagonal line of the square of 156 mm per side is about 220 mm. Thus, the external shape of the n-type single-crystal silicon substrate 2 is the square shape of 156 mm per side with the four corners of the square cut off about 10 mm.

The obtained n-type single-crystal silicon substrate 2 undergoes specification evaluation of whether the conditions such as the thickness and the external dimension of the substrate 2 satisfy predetermined specifications. A substrate satisfying the specifications is used for the, manufacturing of the solar cell 1.

(Surface Cleaning, Texture Formation Step)

In step 2, pyramid-shaped microscopic asperities are formed as a texture structure on the surface of the light-receiving side of the n-type single-crystal silicon substrate 2. A chemical solution in which isopropyl alcohol between about 10 wt % and 15 wt % inclusive is mixed with sodium hydroxide (NaOH) aqueous solution between 5 wt % and 10 wt % inclusive is used in forming the texture structure. The n-type single-crystal silicon substrate 2 is immersed in the chemical solution heated to a temperature between about 80° C. and 90° C. inclusive for about fifteen minutes to twenty minutes. The immersion subjects the surface of the n-type single-crystal silicon substrate 2 to anisotropic etching, thereby forming the microscopic asperities on the entire surface of the n-type single-crystal silicon substrate 2.

Although the chemical solution in which isopropyl alcohol is mixed with a sodium hydroxide aqueous solution is used as an etchant for forming the texture structure in this example, a chemical solution in which a commercially available additive for texture etching is added to an alkaline aqueous solution such as a sodium hydroxide aqueous solution or a potassium hydroxide (KOH) aqueous solution may be used as an etchant. Further, in this step, the n-type single-crystal silicon substrate 2 is etched about 5 μm to 10 μm from the substrate surface, so that a damaged layer formed on the substrate surface during the slicing can be removed at the same time, thereby cleaning the substrate of the n-type single-crystal silicon substrate 2 at the same time. The substrate cleaning of the n-type single-crystal silicon substrate 2 may be performed in advance separately.

(Boron-Containing Oxide Film, Protective Oxide Film Formation Step)

In step 3, to diffuse a p-type impurity into the n-type single-crystal silicon substrate 2, as illustrated in FIG. 5, a boron-containing oxide film 21 and a protective oxide film 22 are formed on one surface of the n-type single-crystal silicon substrate 2 constituting the light-receiving surface. Specifically, the boron-containing oxide film 21 of a thickness of 30 nm is first formed by exposing the n-type single-crystal silicon substrate 2 heated to about 500° C. to a mixed gas atmosphere of silane (SiH₄) gas, oxygen (O₂) gas, and diborane (B₂H₆) gas at atmospheric pressure supplied to a processing chamber.

After the formation of the boron-containing oxide film 21, the supply of diborane into the processing chamber is stopped. The n-type single-crystal silicon substrate 2 is then exposed to a mixed gas atmosphere of silane and oxygen to thereby form the protective oxide film 22 of a thickness of 120 nm on the boron-containing oxide film 21. The protective oxide film 22 of 120 nm, which serves as a capping film for preventing boron from volatilizing into the atmosphere in a subsequent heat treatment step, is formed overlying the boron-containing oxide film 21. A mask film may be formed in advance on a region of the n-type single-crystal silicon substrate 2 that does not need the boron-containing oxide film 21 and the protective oxide film 22, and removed after the protective oxide film 22 is formed.

(p-Type Impurity Diffusion Layer Formation Step)

In step 4, the n-type single-crystal silicon substrate 2 with the boron-containing oxide film 21 and the protective oxide film 22 formed thereon is heat-treated to thereby form the p-type impurity diffusion layer 3 as illustrated in FIG. 6. Specifically, a boat on which the n-type single-crystal silicon substrate 2 is placed is inserted into a horizontal furnace to be subjected to heat treatment at a temperature of about 1050° C. for about thirty minutes. This heat treatment diffuses boron from the boron-containing oxide film 21 into a surface layer of the n-type single-crystal silicon substrate 2, thereby forming the p-type impurity diffusion layer 3 in the surface layer on one side of the n-type single-crystal silicon substrate 2. Such a diffusion of boron enables formation of the p-type impurity diffusion layer 3 of a sheet resistance of about 90 Ω/sq. Boron, which is a p-type impurity, is diffused into silicon at a lower diffusion coefficient of diffusion than n-type impurities such as phosphorus. To diffuse boron into the n-type single-crystal silicon substrate 2, thus, the heat treatment at a higher temperature than in a step of diffusing an n-type impurity described later is required. That is, in the p-type impurity diffusion layer formation step, the heat treatment is performed at the higher temperature than in a first diffusion step and a second diffusion step that are described later.

(n-Type Dopant-Containing Paste Application Step)

In step 5, to form the first n-type impurity diffusion layer 11 which is the high-concentration impurity diffusion layer of the n-type impurity diffusion layer 10, an n-type dopant-containing paste 23 serving as a diffusion-source-containing coating is applied to and formed on the opposite surface of the n-type single-crystal silicon substrate 2 constituting the back surface as illustrated in FIG. 7. Using a screen printing method, the n-type dopant-containing paste 23 is printed in a comb shape corresponding to the shapes of the on-n-type-layer electrodes 14. A resin paste, which is used for the n-type dopant-containing paste 23, is not acid but neutral. This resin paste neither sublimes nor is destroyed by fire at a thermal diffusion temperature that is a heat treatment temperature in the first diffusion step that is step 6 described later.

Main constituent materials of the n-type dopant-containing paste 23 include at least one solvent and at least one kind of glass powder containing an n-type impurity that is to be diffused into the n-type single-crystal silicon substrate 2. The n-type dopant-containing paste 23 may contain another additive in view of application properties. The n-type impurity contained in the glass powder to diffuse the n-type impurity into the n-type single-crystal silicon substrate 2 is at least one element selected from phosphorus (P) and antimony (Sb). The glass powder containing at least one element selected from phosphorus (P) and antimony (Sb) as an n-type impurity contains at least one n-type impurity-containing material selected from P₂O₃, P₂O₅, and Sb₂O₃, and at least one glass-component material selected from SiO₂, K₂O, Na₂O, Li₂O, BaO, SrO, CaO, MgO, BeO, ZnO, PbO, CdO, V₂O₅, SnO, ZrO₂, TiO₂, and MoO₃. The n-type dopant-containing paste 23 is formed by dissolving the above-described glass powder in the solvent into the paste state.

The on-n-type-layer electrodes 14 are formed on the first n-type impurity diffusion layer 11 in a subsequent step to establish electrical contact between the first n-type impurity diffusion layer 11 and the respective on-n-type-layer electrodes 14. The positioning errors of the on-n-type-layer electrodes 14 occur in forming the on-n-type-layer electrodes 14. For this reason, the first n-type impurity diffusion layer 11, which is formed at a location on the surface of the n-type single-crystal silicon substrate 2 where the on-n-type-layer electrodes 14 are to be formed, has a shape that is enlarged outwardly beyond the external shapes of the on-n-type-layer electrodes 14 and thus larger than the shapes of the on-n-type-layer electrodes 14.

Specifically, screen printing of the n-type dopant-containing paste 23 is performed using a screen printing plate having the width of opening larger than the width of the on-n-type-layer electrode 14. For example, when the width of the on-n-type-layer electrode 14 to be formed is set to 50 μm, the width of the n-type dopant-containing paste 23 is set to 150 μm in view of misalignment during the formation of the on-n-type-layer electrode 14.

Pieces of the n-type dopant-containing paste 23, which range in number from one hundred to three hundred, are printed on regions where the on-n-type-layer grid electrodes 15 are to be formed at the back surface of the n-type single-crystal silicon substrate 2. Each of the pieces of the paste 23 printed on the regions where the grid electrodes 15 are to be formed has a width of between 50 μm and 150 μm inclusive. Pieces of the n-type dopant-containing paste 23, which range in number from three to five, are printed on regions on which the on-n-type-layer bus electrodes 16 are to be formed at the back surface of the n-type single-crystal silicon substrate 2. Each of the pieces of the paste 23 printed on the regions where the bus electrodes 16 are to be formed has a width of between 0.5 mm and 1.5 mm inclusive. In the first embodiment, the n-type dopant-containing paste 23 of the width of 150 μm to form the grid electrode formation region where the on-n-type-layer grid electrode 15 of a width of 60 μm is to be formed are printed in one hundred pieces. The n-type dopant-containing paste 23 of a width of 1.2 mm to form the bus electrode formation region where the on-n-type-layer bus electrode 16 of a width of 1.0 mm is to be formed are printed in four pieces.

After the printing of the n-type dopant-containing paste 23, a drying step of drying the n-type dopant-containing paste 23 is performed. When the speed at which the n-type dopant-containing paste 23 is dried after the printing of the n-type dopant-containing paste 23 is slow, the printed n-type dopant-containing paste 23 may spread and thus fail to obtain a desired printed pattern. For this reason, the n-type dopant-containing paste 23 is preferably dried quickly, and is preferably dried by raising the temperature of the n-type dopant-containing paste 23 using a drier such as an infrared heater.

When the n-type dopant-containing paste 23 contains, for example, terpineol as a solvent, the n-type dopant-containing paste 23 is preferably dried at a temperature of 200° C. or higher. When the n-type dopant-containing paste 23 contains ethyl cellulose as a resin component, the n-type dopant-containing paste 23 is preferably dried at a temperature of 400° C. or higher to burn ethyl cellulose. Even when the n-type dopant-containing paste 23 is dried at a temperature lower than 400° C., ethyl cellulose can be burnt in a subsequent diffusion step, which poses no problem.

(First Diffusion Step)

In step 6, after the drying of the n-type dopant-containing paste 23, a boat on which the n-type single-crystal silicon substrate 2 is placed is put into a thermal diffusion furnace to perform first heat treatment as the first diffusion step that is a step of the n-type dopant-containing paste 23 performing thermal diffusion of phosphorus that is an n-type impurity. The first diffusion step is a first stage of a two-stage successive diffusion steps.

The first diffusion step is performed under atmosphere conditions where atmosphere gas such as nitrogen gas (N₂), oxygen gas (O₂), mixed gas of nitrogen and oxygen (N₂/O₂), or the air is circulated in the thermal diffusion furnace. The atmosphere gas is not limited to a particular flow rate. For the mixed atmosphere, atmospheres are not limited to a particular flow ratio, and may be at desired flow rates. The flow rates of mixed gas of nitrogen and oxygen (N₂/O₂) are, for example, N₂: 5.7 SLM and O₂: 0.6 SLM. That is, in the first diffusion step, phosphorous oxychloride (POC1₃) is not used, and hence there are no other diffusion sources of phosphorus that is an n-type impurity than the n-type dopant-containing paste 23. Thus, the first diffusion step diffuses phosphorus from the n-type dopant-containing paste 23 into the n-type single-crystal silicon substrate 2 in an atmosphere not containing phosphorus that is a dopant element, thereby forming the first n-type impurity diffusion layer 11 patterned in a desired pattern.

The first diffusion step is performed, for example, at a temperature between 870° C. and 940° C. inclusive, for a continuous period of time between about five minutes and ten minutes inclusive. This allows the thermal diffusion of phosphorus that is an n-type impurity to be performed only beneath the region of the n-type single-crystal silicon substrate 2 where the n-type dopant-containing paste 23 is printed. As a result, the diffusion of phosphorus that is an n-type impurity is performed only in the region beneath the surface of the n-type single-crystal silicon substrate 2, this region being enlarged outwardly beyond the external shape of region where the on-n-type-layer electrodes 14 are to be formed.

This first diffusion step allows phosphorus that is an n-type impurity to be thermally diffused from the n-type dopant-containing paste 23 at a first diffusion concentration that is the relatively high concentration into the region beneath the region of the surface of the n-type single-crystal silicon substrate 2 where the n-type dopant-containing paste 23 is printed, such that the first n-type impurity diffusion layer 11 is formed as illustrated in FIG. 8. The first n-type impurity diffusion layer 11 is formed in the region beneath the surface of the n-type single-crystal silicon substrate 2, this region being enlarged outwardly beyond the external shape of the region where the on-n-type-layer electrodes 14 are to be formed. The enlarged region defines the region under the on-n-type-layer electrodes 14 and its vicinities in the solar cell 1.

The first n-type impurity diffusion layer 11 is formed in a comb shape to have the same width as the printed width of the printed n-type dopant-containing paste 23. In the first embodiment, the one hundred pieces of the first n-type impurity diffusion layer 11, which define the grid electrode formation regions, are formed in the regions where the on-n-type-layer grid electrodes 15 are to be formed. Each piece of the layer 11 formed on the region where the on-n-type-layer grid electrode 15 is to be formed has a width of 150 μm. The four pieces of the first n-type impurity diffusion layer 11, which define the bus electrode formation regions, are formed in the regions where the on-n-type-layer bus electrodes 16 are to be formed. Each piece of the layer 11 formed on the region where the on-n-type-layer bus electrode 16 is to be formed has a width of 1.2 mm.

In the first embodiment, by forming the first n-type impurity diffusion layer 11 using the n-type dopant-containing paste 23, an n-type impurity can be diffused at the high concentration into the n-type single-crystal silicon substrate 2. Consequently, the first n-type impurity diffusion layer 11 in the range between 20 Ω/sq. and 80 Ω/sq. inclusive can be formed. That is, the first embodiment can provide the first n-type impurity diffusion layer 11 that has a high sheet resistance of 80 Ω/sq. and can reduce the contact resistance with the on-n-type-layer electrodes 14. On the other hand, by adjusting conditions on, for example, the n-type dopant-containing paste 23 and heat treatment conditions, the first n-type impurity diffusion layer 11 having a sheet resistance of 20 Ω/sq. or higher, which is required from the standpoint of current utility, can be achieved.

When thermal diffusion is performed under the condition of containing oxygen gas (O₂) in the first diffusion step, a thin oxide film not shown is formed under the influence during the thermal diffusion on regions of the surface of the n-type single-crystal silicon substrate 2 where the n-type dopant-containing paste 23 is not printed.

(Second Diffusion Step)

In step 7, after the completion of the first diffusion step, a second heat treatment is subsequently performed as a second diffusion step that is a step of phosphorous oxychloride (POC1₃) performing thermal diffusion of phosphorus that is an n-type impurity. That is, after the first diffusion step, the second diffusion step is performed in succession to the first diffusion step in the same thermal diffusion furnace without the n-type single-crystal silicon substrate 2 being taken out of the thermal diffusion furnace. The second diffusion step is a second stage of the two-stage successive diffusion steps.

The second diffusion step is performed under the presence of phosphorous oxychloride (POCl₃) gas in the thermal diffusion furnace. Specifically, the first diffusion step performs the thermal diffusion under the atmosphere condition not containing phosphorous oxychloride (POCl₃) while the second diffusion step performs the thermal diffusion under the atmosphere condition containing phosphorous oxychloride (POCl₃) as a diffusion source of phosphorus that is an n-type impurity. The flow rate of the atmosphere gas is not limited to a particular one, and may be set appropriately under conditions such as diffusion concentration, diffusion temperature, and diffusion time. The second diffusion step is performed, for example, at a lower temperature between 800° C. and 840° C. inclusive than the temperature between 870° C. and 900° C. inclusive in the first diffusion step, for a continuous period of time between about ten minutes and twenty minutes inclusive.

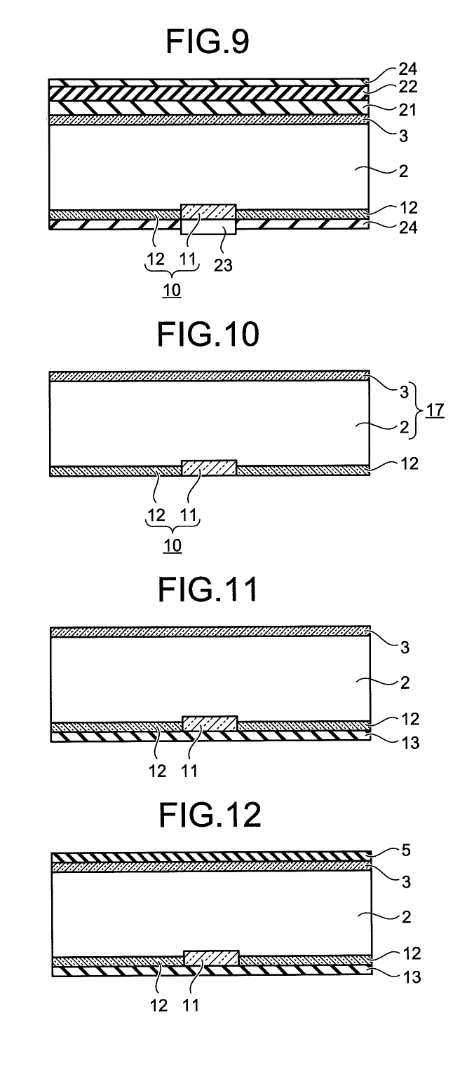

This second diffusion step allows phosphorus that is an n-type impurity to be thermally diffused at the second diffusion concentration that is the concentration relatively lower than that in the first n-type impurity diffusion layer 11, into regions other than the region of the surface of the n-type single-crystal silicon substrate 2 where the n-type dopant-containing paste 23 is printed, such that the second n-type impurity diffusion layer 12 is formed as illustrated in FIG. 9. Further, a phosphosilicate glass (PSG) layer that is a glassy layer 24, which was deposited on the surface of the n-type single-crystal silicon substrate 2 during the diffusion processing is formed on this surface immediately after the second diffusion step.

After the second diffusion step, the impurity concentration at the surface of the first n-type impurity diffusion layer 11 is between 5×10²⁰ atoms/cm³ and 2×10²¹ atoms/cm³ inclusive, and the phosphorus concentration at the surface of the second n-type impurity diffusion layer 12 is between 5×10¹⁹ atoms/cm³ and 2×10²⁰ atoms/cm³ inclusive. Since the impurity concentration at the surface of the first n-type impurity diffusion layer 11 and the phosphorus concentration at the surface of the second n-type impurity diffusion layer 12 after the second diffusion step are in the above-described ranges, the structure of the solar cell 1 can achieve a high photoelectric conversion efficiency.

Further, in the first diffusion step, phosphorus that is an n-type impurity is contained in the glass powder of the n-type dopant-containing paste 23, and thus is less likely to be volatilized even during the first heat treatment. This prevents phosphorus from being diffused due to the generation of volatilization gas into the regions of the surface of the n-type single-crystal silicon substrate 2 where the n-type dopant-containing paste 23 is not applied. As a result, the second n-type impurity diffusion layer 12 is formed only through the vapor-phase diffusion in the second diffusion step, so that the diffusion concentration of phosphorus in the second n-type impurity diffusion layer 12 can be kept low to thereby provide the second n-type impurity diffusion layer 12 with the sheet resistance greater than 150 Ω/sq.

In the first diffusion step and the second diffusion step, the heat treatment is performed at lower temperatures than in the p-type impurity diffusion layer formation step. Heat treatment in the p-type impurity diffusion layer formation step is performed before the first diffusion step and the second diffusion step. This is because if the heat treatment in the p-type impurity diffusion layer formation step is performed after the first diffusion step and the second diffusion step, the high-temperature heat treatment in the p-type impurity diffusion layer formation step affects the first n-type impurity diffusion layer 11 and the second n-type impurity diffusion layer 12, thereby changing their sheet resistances. When the heat treatment in the p-type impurity diffusion layer formation step is performed before the first diffusion step and the second diffusion step, the p-type impurity diffusion layer is hardly affected by the heat treatments in the first diffusion step and the second diffusion step because boron that is a p-type impurity is diffused into silicon at a lower diffusion coefficient than n-type impurities such as phosphorus.

(p-n Separation Step)

In step 8, p-n separation is performed to electrically insulate the on-n-type-layer electrodes 14 and the on-p-type-layer electrodes 7, which are the electrodes formed in a subsequent step. Since the n-type impurity diffusion layer 10 is formed uniformly over the surface of the n-type single-crystal silicon substrate 2, the front and back surfaces are electrically connected. Thus, when the on-n-type-layer electrodes 14 and the on-p-type-layer electrodes 7 are formed with these front and back surfaces in such an electrically connected state, the on-n-type-layer electrodes 14 and the on-p-type-layer electrodes 7 are electrically connected. To break this electrical connection, the second n-type impurity diffusion layer 12 formed on the end face regions of the n-type single-crystal silicon substrate 2 is etching-removed by dry etching to thereby perform the p-n separation. As another method performed to remove the influence of the second n-type impurity diffusion layer 12, there is a method of performing end face separation by a laser.

(Glassy Layer Removal Step)

In step 9, as illustrated in FIG. 10, the impurity-containing layers containing the impurities formed on the n-type single-crystal silicon substrate 2 are removed. Specifically, the n-type single-crystal silicon substrate 2 is immersed in a 10% hydrofluoric acid solution for about 360 seconds, for example, and then subjected to aqueous cleaning processing. This removes the boron-containing oxide film 21, the protective oxide film 22, the n-type dopant-containing paste 23, and the glassy layer 24 formed on the surfaces of the n-type single-crystal silicon substrate 2. This results in the semiconductor substrate 17 having the p-n junction formed by the semiconductor substrate 2 made of n-type silicon that is the first conductive layer, and the p-type impurity diffusion layer 3 that is the second conductive layer formed on the light-receiving side of the semiconductor substrate 2. Further, the selective impurity diffusion layer structure formed of the first n-type impurity diffusion layer 11 and the second n-type impurity diffusion layer 12 is obtained as the n-type impurity diffusion layer 10 on the back side of the n-type single-crystal silicon substrate 2.

(On-n-Type-Layer Passivation Film Formation Step)

In step 10, as illustrated in FIG. 11, the on-n-type-layer passivation film 13 that is a passivation film on the n-type impurity diffusion layer side is formed on the back surface of the semiconductor substrate 17 on which the n-type impurity diffusion layer 10 is formed. The on-n-type-layer passivation film 13 is a silicon nitride (SiN) film having a refraction index of 2.1 and a thickness of 80 nm and formed using a plasma CVD method using mixed gas of silane gas and ammonia (NH₃) gas as base materials. The on-n-type-layer passivation film 13 may be formed by another method such as a vapor deposition method or a thermal CVD method.

(On-p-Type-Layer Passivation Film Formation Step)

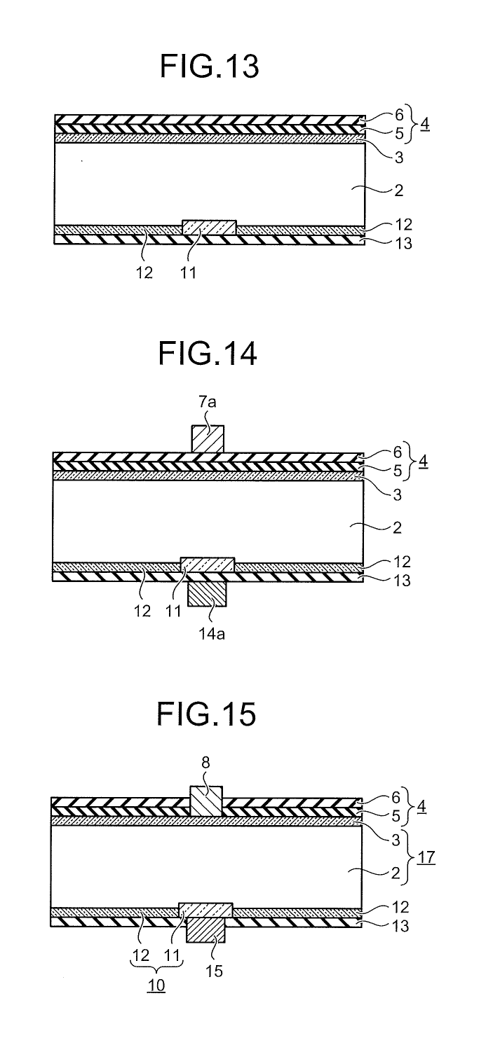

In step 11, the on-p-type-layer passivation film 4 that is a passivation film on the p-type impurity diffusion layer side is formed on the light-receiving surface of the semiconductor substrate 17 on which the p-type impurity diffusion layer 3 is formed. First, to obtain favorable passivation performance relative to the p-type impurity diffusion layer 3, as illustrated in FIG. 12, an aluminum oxide film 5 having negative fixed charge of a thickness of 5 nm is formed. Next, as illustrated in FIG. 13, a silicon nitride film 6 of a refraction index of 2.1 and a thickness of 80 nm is formed using a plasma CVD method. To form solar cells at low prices, the aluminum oxide film 5 need not be formed. The on-p-type-layer passivation film 4 functions also as an anti-reflective film.

(Electrode Formation Step)

In step 12, as illustrated in FIG. 14, electrodes are printed by screen printing and dried to form the dried electrodes. First, an Ag-containing paste 14a that is an electrode material paste containing Ag and glass frit is applied onto the on-n-type-layer passivation film 13 on the back side of the semiconductor substrate 17 by screen printing in the shapes of the on-n-type-layer grid electrodes 15 and the on-n-type-layer bus electrodes 16. Thereafter, the Ag-containing paste 14a is dried to form the dried on-n-type-layer electrodes 14 that define on-n-type-impurity-diffusion-layer electrodes. The Ag-containing paste 14a is dried at 250° C. for five minutes, for example.

Here, the on-n-type-layer electrodes 14 are to be formed within the regions of the first n-type impurity diffusion layer 11 formed in the first diffusion step in step 6, the regions of the first n-type impurity diffusion layer 11 being defined by the widths each of which is 150 μm and the widths each of which is 1.2 mm. Thus, the on-n-type-layer electrodes 14 need to be formed on the first n-type impurity diffusion layer 11 in alignment therewith. In the first embodiment, after the first n-type impurity diffusion layer 11 and the second n-type impurity diffusion layer 12 are formed by the first diffusion step and the second diffusion step which are the two-stage continuous successive steps, the back side of the semiconductor substrate 17 on which the on-n-type-layer passivation film 13 is formed is irradiated with infrared rays and the picture of the irradiated back side of the substrate 17 is taken by an infrared camera. This enables the first n-type impurity diffusion layer 11 and the second n-type impurity diffusion layer 12 to be identified. By thus identifying the positions of the regions of the first n-type impurity diffusion layer 11 and determining the positions at which to print the Ag-containing paste 14a, the Ag-containing paste 14a can be accurately printed on the first n-type impurity diffusion layer 11.

Next, an AgAl-containing paste 7a, which is an electrode material paste containing Ag, Al and glass frit, is applied onto the on-p-type-layer passivation film 4 on the light-receiving side of the semiconductor substrate 17 by screen printing in the shapes of the on-p-type-layer grid electrodes 8 and the on-p-type-layer bus electrodes 9. Thereafter, the AgAl-containing paste 7a is dried to form the dried on-p-type-layer electrodes 7 which define the on-p-type-impurity-diffusion-layer electrodes. To maintain favorable electrical conduction between the respective on-p-type-layer electrodes 7 and the p-type impurity diffusion layer 3, in this example, an AgAl paste containing about 3 wt % Al is used. The AgAl-containing paste 7a is dried at 250° C. for five minutes, for example.

In step 13, the electrode material pastes printed and dried on the light-receiving side and the back side of the semiconductor substrate 17 are fired at the same time. Specifically, the semiconductor substrate 17 is introduced into a firing furnace, and subjected to heat treatment in the atmosphere at a temperature of a peak temperature between about 600° C. and 900° C. inclusive, e.g. 800° C. for a short period of time of three seconds. Consequently, resin components in the electrode material pastes disappear. On the light-receiving side of the semiconductor substrate 17, the glass material contained in the AgAl-containing paste 7a of the on-p-type-layer electrodes 7 melts and penetrates the silicon nitride film 6 and the aluminum oxide film 5 while the silver material contacts the silicon of the p-type impurity diffusion layer 3 and resolidifies. This provides the on-p-type-layer grid electrodes 8 and the on-p-type-layer bus electrodes 9, which define the on-p-type-layer electrodes 7, as illustrated in FIG. 15, thereby ensuring electrical conduction between the respective on-p-type-layer electrodes 7 and the silicon of the semiconductor substrate 17.

On the back side of the semiconductor substrate 17, the glass material contained in the Ag-containing paste 14a of the on-n-type-layer electrodes 14 melts and penetrates the silicon nitride film that is the on-n-type-layer passivation film 13 while the silver material contacts the silicon of the first n-type impurity diffusion layer 11 and resolidifies. This provides the on-n-type-layer grid electrodes 15 and the on-n-type-layer bus electrodes 16, which define the on-n-type-layer electrodes 14, as illustrated in FIG. 15, thereby ensuring electrical conduction between the respective on-n-type-layer electrodes 14 and the silicon of the semiconductor substrate 17.

By performing the steps discussed as above, the solar cell 1 according to the first embodiment illustrated in FIGS. 1 to 3 can be produced. The order of disposition of pastes, which are electrode materials, onto the semiconductor substrate 17 may be changed between the light-receiving side and the back side.

In the method of manufacturing the solar cell 1 according to the first embodiment described above, the n-type dopant-containing paste 23 is applied to the n-type single-crystal silicon substrate 2. The first diffusion step is then performed under conditions where there are no other diffusion sources of phosphorus that is a dopant than the n-type dopant-containing paste 23, thereby forming the first n-type impurity diffusion layer 11. After the first diffusion step, the second diffusion step is performed using phosphorous oxychloride (POC1₃) as a phosphorus diffusion source in the same thermal diffusion furnace without the n-type single-crystal silicon substrate 2 being taken out of the thermal diffusion furnace in which the first diffusion step has been performed. As a result of the performance of the second diffusion step, the second n-type impurity diffusion layer 12 is formed. That is, the two-stage successive diffusion steps defined by the first diffusion step using the n-type dopant-containing paste 23 and the second diffusion step using phosphorous oxychloride (POC1₃) are performed without the n-type single-crystal silicon substrate 2 being taken out of the thermal diffusion furnace. Thus, phosphorus diffusion processing can be efficiently performed to easily make the first n-type impurity diffusion layer 11 and the second n-type impurity diffusion layer 12 to form the selective impurity diffusion layer structure. Consequently, the n-type impurity diffusion layer 10 having the selective impurity diffusion layer structure can be formed easily and at low cost without performing a plurality of complicated steps.

Next, the results of investigation on the dependency of the open-circuit voltage of the solar cell 1 on the sheet resistance of the second n-type impurity diffusion layer 12 will be described. The open-circuit voltage of the solar cell 1 was evaluated based on implied-Voc after the passivation films were formed on the front and back surfaces of the semiconductor substrate 17 so as to perform more accurate measurement eliminating the impact of damage to the impurity diffusion layers when the glass component contained in the electrode material pastes erodes the silicon of the impurity diffusion layers at the front surface and the back surface of the semiconductor substrate 17 during firing of the electrode material pastes. The region of a width of 150 pm of the first n-type impurity diffusion layer 11 is provided in one hundred in number, and the on-n-type-layer grid electrodes 15 are formed on these one hundred regions. The region of a width of 1.2 mm of the first n-type impurity diffusion layer 11 is provided in four in number, and the on-n-type-layer bus electrodes 16 are formed on these four regions. The electrode width of the on-n-type-layer grid electrode 15 is 60 μm, and the electrode width of the on-n-type-layer bus electrode 16 is 1.0 mm.

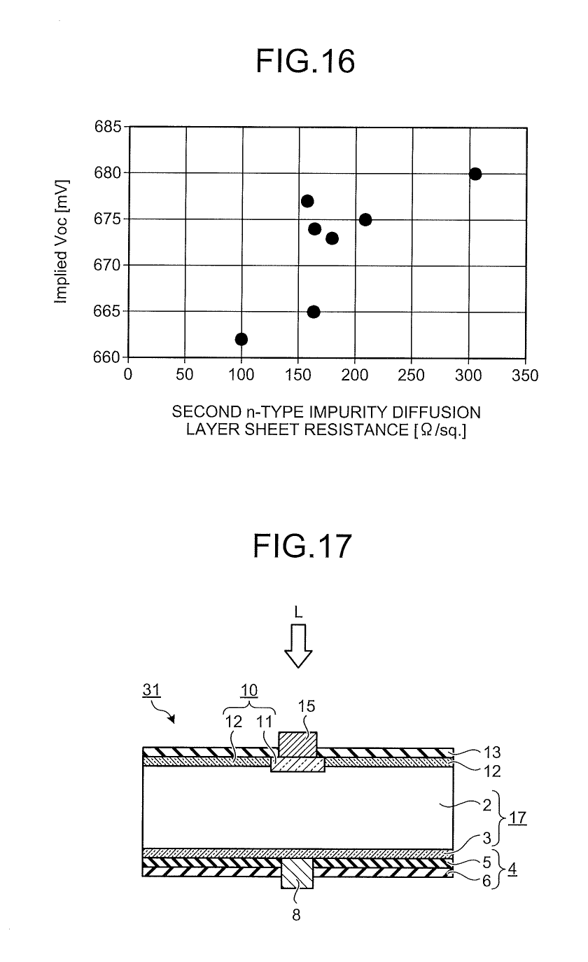

FIG. 16 is a characteristic diagram illustrating the relationship between the sheet resistance (Ω/sq.) of the second n-type impurity diffusion layer 12 and Implied-Voc (mV) at the completion of formation of the on-p-type-layer passivation film 4 in step 11 in solar cell samples produced with various sheet resistances of the second n-type impurity diffusion layer 12 according to the solar cell manufacturing method according to the first embodiment. In FIG. 16, the horizontal axis represents the sheet resistance (Ω/sq.) of the second n-type impurity diffusion layer 12, and the vertical axis represents Implied-Voc (mV) at the completion of step 11. Implied-Voc is an index for evaluating the open-circuit voltage of a solar cell under conditions where no electrodes are formed, in a noncontact manner. Although it is practically necessary to form electrodes on a solar cell, Implied-Voc is a typical index as one of indices for relative comparison on a structure before electrodes are formed. Implied-Voc is evaluated as a value 15 mV to 20 mV higher than an actual open-circuit voltage of the solar cell, depending on used electrodes. As described in the explanation of step 13 described above, the electrode material pastes react with the semiconductor layers during firing of the electrodes. Consequently, the regions covered by the electrodes on the semiconductor layers, that is, the regions contacting the electrodes on the semiconductor layers are eroded by the electrodes, so that the normal surface state of the semiconductor layers is physically damaged. Thus recombination occurs at an interface, and the actual open-circuit voltage decreases against the Implied-Voc.

FIG. 16 shows that when the sheet resistance of the second n-type impurity diffusion layer 12 exceeds 150 Ω/sq., Implied-Voc exceeding 670 mV can be obtained. Thus, it has been confirmed that the sheet resistance of the second n-type impurity diffusion layer 12 is preferably at least greater than 150 Ω/sq. in order that the solar cell having the BSF layer of the selective impurity diffusion layer structure on the back surface thereof obtains a high photoelectric conversion efficiency.

In the structure of the solar cell produced through the manufacturing steps in the first embodiment described above, 680 mV obtained at 300 Ω/sq. is nearly a limit value as an Implied-Voc value. Thus, the sheet resistance of the second n-type impurity diffusion layer 12 is preferably ideally about 300 Ω/sq. As compared to a solar cell not having a BSF layer of any selective impurity diffusion layer structure on the back surface thereof, however, the solar cell produced through the manufacturing steps in the first embodiment can provide a required high photoelectric conversion efficiency at a low cost provided that the solar cell has an Implied-Voc value of 670 mV. In view of the capacity of equipment of a vapor-phase diffusion apparatus for forming n-type layers, 150 Ω/sq. is the lower limit level in setting the sheet resistance of the second n-type impurity diffusion layer 12 that is the high sheet resistance region, taking account of variation in the sheet resistance in equipment of a typical vapor-phase diffusion apparatus. That is, a typical vapor-phase diffusion apparatus can perform vapor phase diffusion processing on two hundred to three hundred silicon substrates at a time. However, if a target average value of the sheet resistance of the second n-type impurity diffusion layer 12 is set to a higher value of 300 Ω/sq., some exceeding 1000 Ω/sq can be formed. Taking account of such variations in the sheet resistance of the second n-type impurity diffusion layer 12, the lower limit level of the sheet resistance of the second n-type impurity diffusion layer 12 is preferably set to 150 Ω/sq.

In FIG. 16, when the sheet resistance of the second n-type impurity diffusion layer 12 exceeded 150 Ω/sq., the concentration of phosphorus at the surface of the second n-type impurity diffusion layer 12 was between 5×10¹⁹ atoms/cm³ and 2×10²⁰ atoms/cm³ inclusive, and the concentration of phosphorus at the surface of the first n-type impurity diffusion layer 11 was between 5×10²⁰ atoms/cm³ and 2×10²¹ atoms/cm³ inclusive. The measured concentration of phosphorus at the completion of formation of the on-p-type-layer passivation film 4 in step 11 are equal to that after the second diffusion step in step 7.

In FIG. 16, the sheet resistance of the first n-type impurity diffusion layer 11 when the sheet resistance of the second n-type impurity diffusion layer 12 exceeded 150 Ω/sq. was in the range between 20 Ω/sq. and 80 Ω/sq. inclusive.

The width of the first n-type impurity diffusion layer 11 depends on a printing technique of printing the n-type dopant-containing paste 23. Currently, by using a printer with high printing position accuracy, the printing of the n-type dopant-containing paste 23 of a width of about 50 μm can be achieved, and the first n-type impurity diffusion layer 11 of a width of about 50 μm can be achieved. When the width of the first n-type impurity diffusion layer 11 is about 50 μm, the width of the on-n-type-layer electrode 14 that is the on-n-type-impurity-diffusion-layer electrode formed on the first n-type impurity diffusion layer 11 is about 40 μm.

The open-circuit voltage studied as described above is known to depend on the area and constituent ratio of the first n-type impurity diffusion layer 11 and the second n-type impurity diffusion layer 12. It is preferable that the second n-type impurity diffusion layer 12 has a larger area and a higher constituent ratio. From this viewpoint, when the n-type single-crystal silicon substrate 2 in a square shape of an external dimension of 156 mm per side is used and the width of the first n-type impurity diffusion layer 11 is set to 50 μm, up to three hundred on-n-type-layer grid electrodes 15 can be formed. When the number of the on-n-type-layer grid electrodes 15 is greater than 300, the area of the second n-type impurity diffusion layer 12 becomes too narrow and the constituent ratio becomes too low with the result that the open-circuit voltage can decrease.

On the other hand, in terms of current collection efficiency, it is preferable to increase the number of the on-n-type-layer grid electrodes 15. From this viewpoint, when the n-type single-crystal silicon substrate 2 of an external dimension of 156 mm per side is used and the width of the first n-type impurity diffusion layer 11 is set to 50 μm, it is preferable to form one hundred or more on-n-type-layer grid electrodes 15. When the number of the on-n-type-layer grid electrodes 15 is less than 100, the current collection efficiency on the back surface of the solar cell 1 decreases, and the open-circuit voltage decreases.

The sheet resistance value described above represents the sheet resistance value of only the first n-type impurity diffusion layer 11 or the second n-type impurity diffusion layer 12. In general, when an n-type impurity diffusion layer is formed on an n-type silicon substrate through diffusion of an n-type impurity, it is difficult to measure the sheet resistance of only the n-type impurity diffusion layer because current flows also between the n-type silicon substrate and the n-type impurity diffusion layer. To measure the sheet resistance of only the n-type impurity diffusion layer, a sheet resistance value obtained when the n-type dopant-containing paste 23 is printed on a p-type silicon substrate and subjected to heat treatment may be used. When the n-type impurity diffusion layer is formed on the p-type silicon substrate, the p-n junction prevents current from flowing between the p-type silicon substrate and the n-type impurity diffusion layer. Thus, measuring the sheet resistance of the n-type impurity diffusion layer by a measurement method such as a four-terminal method from the surface of the n-type impurity diffusion layer enables measuring the sheet resistance of only the n-type impurity diffusion layer. The sheet resistance of the second n-type impurity diffusion layer 12 in FIG. 16 is a value obtained when the second n-type impurity diffusion layer 12 is formed on the p-type silicon substrate according to the method from step 1 to step 7 described above. The concentration of phosphorus at the surface of the second n-type impurity diffusion layer 12 and the concentration of phosphorus at the surface of the first n-type impurity diffusion layer 11 when the sheet resistance of the second n-type impurity diffusion layer 12 exceeds 150 Ω/sq. in FIG. 16 are values obtained when the first n-type impurity diffusion layer 11 and the second n-type impurity diffusion layer 12 are formed on the p-type silicon substrate according to the method from step 1 to step 7 described above.

That is, the sheet resistance of the n-type impurity diffusion layer formed by printing the n-type dopant-containing paste 23 on the p-type silicon substrate and subjecting the printed paste to the heat treatment is measured, a diffusion condition under which the sheet resistance is in the above-described range is derived, and the n-type impurity diffusion layer is formed on the n-type silicon substrate under that diffusion condition. Thus, the n-type impurity diffusion layer on the n-type silicon substrate can be in the above-described sheet resistance range.

Steps 6 and 7, which perform the two-stage successive diffusions described above, employ a heat application process of first forming the first n-type impurity diffusion layer 11, and then forming the second n-type impurity diffusion layer 12. The heat application process is not limited to this, and may be performed in the order in which the second n-type impurity diffusion layer 12 is first formed, and then the first n-type impurity diffusion layer 11 is formed. That is, the order of execution of step 6 and step 7 described above may be changed.

In this case, first, a step of using phosphorous oxychloride (POC1₃) gas to thermally diffuse phosphorus that is an n-type impurity is performed after the execution of step 5. That is, in the thermal diffusion furnace, a thermal diffusion step is performed on the n-type single-crystal silicon substrate 2 under the atmosphere condition containing phosphorous oxychloride (POC1₃) gas as a diffusion source of phosphorus that is an n-type impurity.

The flow rate of the atmosphere gas is not limited to a particular one, and may be set appropriately under conditions such as diffusion concentration, diffusion temperature, and diffusion time. This thermal diffusion is performed at a temperature between 800° C. and 840° C. inclusive, for a continuous period of time between about ten minutes and twenty minutes inclusive, for example. This heat treatment allows phosphorus that is an n-type impurity to be thermally diffused into regions other than the regions of the printed n-type dopant-containing paste 23 at the surface of the n-type single-crystal silicon substrate 2, thereby forming the second n-type impurity diffusion layer 12.

Next, in succession to the step of forming the layer 12, a step of using the n-type dopant-containing paste 23 to thermally diffuse phosphorus that is an n-type impurity is performed in the same thermal diffusion furnace without the n-type single-crystal silicon substrate 2 being taken out of the thermal diffusion furnace. This thermal diffusion step is performed under atmosphere conditions where atmosphere gas such as nitrogen gas (N₂), oxygen gas (O₂), mixed gas of nitrogen and oxygen (N₂/O₂), or the air is circulated in the thermal diffusion furnace. This thermal diffusion step is performed at a temperature between 870° C. and 940° C. inclusive, for a continuous period of time between about five minutes and ten minutes inclusive, for example. The atmosphere gas is not limited to a particular flow rate. For mixed atmosphere, atmospheres are not limited to a particular flow ratio, and may be at desired flow rates. The flow rates of mixed gas of nitrogen and oxygen (N₂/O₂) are, for example, N₂: 5.7 SLM and O₂: 0.6 SLM. That is, in this thermal diffusion step, phosphorous oxychloride (POC1₃) is not used, and hence there are no other diffusion sources of phosphorus that is an n-type impurity than the n-type dopant-containing paste 23. Thus, this thermal diffusion step diffuses phosphorus from the n-type dopant-containing paste 23 into the n-type single-crystal silicon substrate 2 in an atmosphere not containing phosphorus that is a dopant element, thereby forming the first n-type impurity diffusion layer 11 patterned in a desired pattern.

As described above, in the first embodiment, the first diffusion step in which only the n-type dopant-containing paste 23 is used as a diffusion source of phosphorus that is an n-type impurity, and the second diffusion step in which only atmosphere gas containing phosphorus is used as a diffusion source of phosphorus that is an n-type impurity are performed. Thus, in the first embodiment, the first n-type impurity diffusion layer 11 and the second n-type impurity diffusion layer 12 can be made easily without performing a plurality of complicated steps, to form the n-type impurity diffusion layer 10 having the selective impurity diffusion layer structure easily and at low cost.

Further, in the first embodiment, the impurity concentration at the surface of the first n-type impurity diffusion layer 11 is set in the range between 5×10²⁰ atoms/cm³ and 2×10²¹ atoms/cm³ inclusive, and the phosphorus concentration at the surface of the second n-type impurity diffusion layer 12 is set in the range between 5×10¹⁹ atoms/cm³ and 2×10²⁰ atoms/cm³ inclusive. Since the impurity concentration at the surface of the first n-type impurity diffusion layer 11 and the concentration of phosphorus at the surface of the second n-type impurity diffusion layer 12 are such appropriate concentrations, the solar cell 1 having the n-type impurity diffusion layer 10 having the selective impurity diffusion layer structure on the back side of the n-type single-crystal silicon substrate 2 can achieve a high photoelectric conversion efficiency.

Further, in the first embodiment, the sheet resistance of the first n-type impurity diffusion layer 11 is set in the range between 20 Ω/sq. and 80 Ω/sq. inclusive, and the sheet resistance of the second n-type impurity diffusion layer 12 is set greater than 150 Ω/sq. Since the sheet resistance of the first n-type impurity diffusion layer 11 and the sheet resistance of the second n-type impurity diffusion layer 12 are such appropriate resistance values, the solar cell 1 having the n-type impurity diffusion layer 10 having the selective impurity diffusion layer structure on the back side of the n-type single-crystal silicon substrate 2 can achieve a high photoelectric conversion efficiency.

### Second Embodiment

FIG. 17 is a cross-sectional view of a major part illustrating the configuration of a solar cell 31 according to a second embodiment of the present invention. FIG. 17 is the cross-sectional view corresponding to FIG. 3. In FIG. 17, the same members as those of the solar cell 1 according to the first embodiment are given the same reference numerals. The solar cell 31 according to the second embodiment has an inverted configuration of the solar cell 1 according to the first embodiment. That is, in the solar cell 1 according to the first embodiment, the p-n junction formed by the n-type single-crystal silicon substrate 2 and the p-type impurity diffusion layer 3 is formed on the light-receiving side of the solar cell 31, and the n-type impurity diffusion layer 10 is formed as a BSF layer on the back side of the n-type single-crystal silicon substrate 2.

On the other hand, in the solar cell 31 according to the second embodiment, a p-n junction formed by an n-type single-crystal silicon substrate 2 and a p-type impurity diffusion layer 3 is formed on the back side of the solar cell 31, and an n-type impurity diffusion layer 10 is formed as a front surface field (FSF) layer on the light-receiving side of the n-type single-crystal silicon substrate 2. The front surface field (FSF) layer has the same function and effect as the BSF layer. In the solar cell 31, light L enters from an on-n-type-layer passivation film 13. That is, in the solar cell 31, the on-n-type-layer passivation film 13 side is the light-receiving side, and the on-p-type-layer passivation film 4 side is the back side. The solar cell 31 is formed by the same manufacturing method as the solar cell 1 according to the first embodiment.

The solar cell 31 according to the second embodiment also provides the same effects as the solar cell 1 according to the first embodiment described above. In the solar cell 31 according to the second embodiment, the amount of absorption of light L in the p-type impurity diffusion layer 3 is reduced, so that the photoelectric conversion efficiency is increased as compared to the solar cell 1.

The configurations illustrated in the above embodiments illustrate an example of the subject matter of the present invention, and can be combined with another known art, and can be partly omitted or changed without departing from the scope of the present invention.

### REFERENCE SIGNS LIST

1 and 31 solar cell, 2 semiconductor substrate, 3 p-type impurity diffusion layer, 4 on-p-type-impurity-diffusion-layer passivation film, 5 aluminum oxide film, 6 silicon nitride film, 7 on-p-type-impurity-diffusion-layer electrode, 7a AgAl-containing paste, 8 on-p-type-impurity-diffusion-layer grid electrode, 9 on-p-type-impurity-diffusion-layer bus electrode, 10 n-type impurity diffusion layer, 11 first n-type impurity diffusion layer, second n-type impurity diffusion layer, 13 on-n-type-impurity-diffusion-layer passivation film, 14 on-n-type-impurity-diffusion-layer electrode, 14a Ag-containing paste, 15 on-n-type-impurity-diffusion-layer grid electrode, 16 on-n-type-impurity-diffusion-layer bus electrode, 17 semiconductor substrate, 21 boron-containing oxide film, 22 protective oxide film, 23 n-type dopant-containing paste, 24 glassy layer.

1-11. (canceled)

12. A solar cell comprising:
an n-type silicon substrate;
a p-type impurity diffusion layer formed on one side of the n-type silicon substrate and containing a p-type impurity element;
an n-type impurity diffusion layer formed on an opposite side of the n-type silicon substrate and containing an n-type impurity element at a higher concentration than the n-type silicon substrate, the n-type impurity diffusion layer having a first n-type impurity diffusion layer in which an n-type impurity element is diffused at a first concentration, and a second n-type impurity diffusion layer in which an n-type impurity element is diffused at a second concentration lower than the first concentration;
on-p-type-impurity-diffusion-layer electrodes formed on the p-type impurity diffusion layer; and
on-n-type-impurity-diffusion-layer electrodes formed on the first n-type impurity diffusion layer, wherein
a concentration of the n-type impurity element at a surface of the first n-type impurity diffusion layer is between 5×10²⁰ atoms/cm³ and 2×10²¹ atoms/cm³ inclusive, and a concentration of the n-type impurity element at a surface of the second n-type impurity diffusion layer is between 5×10¹⁹ atoms/cm³ and 2×10²⁰ atoms/cm³ inclusive.

13. The solar cell according to claim 12, wherein
a sheet resistance of the first n-type impurity diffusion layer is between 20 Ω/sq. and 80 Ω/sq. inclusive, and a sheet resistance of the second n-type impurity diffusion layer is greater than 150 Ω/sq.

14. The solar cell according to claim 12, wherein
an external shape of the n-type silicon substrate is a square shape of a length of between 156 mm and 158 mm inclusive per side,
the first n-type impurity diffusion layer has elongated grid electrode formation regions each of which has a width of between 50 μm and 150 μm inclusive, the regions ranging in number from one hundred to three hundred inclusive, and
the on-n-type-impurity-diffusion-layer electrodes have elongated on-n-type-impurity-diffusion-layer grid electrodes within regions of the grid electrode formation regions, the on-n-type-impurity-diffusion-layer grid electrodes ranging in number from one hundred to three hundred inclusive.

15. The solar cell according to claim 12, wherein
the n-type impurity element is phosphorus.

16. A solar cell manufacturing method, comprising:
a first step of forming a p-type impurity diffusion layer containing a p-type impurity element on one side of an n-type silicon substrate;
a second step of applying an n-type dopant-containing paste containing an n-type impurity element to an opposite side of the n-type silicon substrate;
a third step of subjecting the n-type silicon substrate to a first heat treatment under gas atmosphere not containing an n-type impurity element in a processing chamber to allow the n-type impurity element to be diffused from the n-type dopant-containing paste into a region of the n-type silicon substrate under the n-type dopant-containing paste to thereby form a first n-type impurity diffusion layer in the region of the n-type silicon substrate under the n-type dopant-containing paste, the first n-type impurity diffusion layer having the n-type impurity element diffused at a first concentration;
a fourth step of subjecting the n-type silicon substrate to a second heat treatment under dopant-containing gas atmosphere containing an n-type impurity element in the processing chamber to allow the n-type impurity element to be diffused from the dopant-containing gas into unapplied regions having the n-type dopant-containing paste not applied thereon on the opposite side of the n-type silicon substrate to thereby form a second n-type impurity diffusion layer in the unapplied regions, the second n-type impurity diffusion layer having the n-type impurity element diffused at a second concentration lower than the first concentration;
a fifth step of removing the n-type dopant-containing paste;
a sixth step of forming on-p-type-impurity-diffusion-layer electrodes on the p-type impurity diffusion layer; and
a seventh step of forming on-n-type-impurity-diffusion-layer electrodes on the first n-type impurity diffusion layer.

17. The solar cell manufacturing method according to claim 16, wherein
a concentration of the n-type impurity element at a surface of the first n-type impurity diffusion layer after the fourth step is between 5×10²⁰ atoms/cm³ and 2×10²¹ atoms/cm³ inclusive, and a concentration of the n-type impurity element at a surface of the second n-type impurity diffusion layer after the fourth step is between 5×10¹⁹ atoms/cm³ and 2×10²⁰ atoms/cm³ inclusive.

18. The solar cell manufacturing method according to claim 16, wherein
after the fourth step, a sheet resistance of the first n-type impurity diffusion layer is between 20 Ω/sq. and 80 Ω/sq. inclusive and a sheet resistance of the second n-type impurity diffusion layer is greater than 150 Ω/sq.

19. The solar cell manufacturing method according to claim 18, wherein the method further comprises,
between the fifth step and the sixth step,
a step of forming an on-n-type-impurity-diffusion-layer passivation film on the opposite side of the n-type silicon substrate on which the first n-type impurity diffusion layer and the second n-type impurity diffusion layer are formed, and
a step of forming an on-p-type-impurity-diffusion-layer passivation film on the one side of the n-type silicon substrate on which the first n-type impurity diffusion layer and the second n-type impurity diffusion layer are formed
and wherein, ‘after formation of the on-n-type-impurity-diffusion-layer passivation film and the on-p-type-impurity-diffusion-layer passivation film, Implied-Voc is 665 mV or more, the Implied-Voc being an open-circuit voltage of the solar cell in a state where the on-p-type-impurity-diffusion-layer electrodes and the on-n-type-impurity-diffusion-layer electrodes are not formed.

20. The solar cell manufacturing method according to claim 19, wherein
the Implied-Voc is 670 mV or more.

21. The solar cell manufacturing method according to claim 16, wherein
an external shape of the n-type silicon substrate is a square shape of a length of between 156 mm and 158 mm inclusive per side,
the third step forms pieces of the first n-type impurity diffusion layer that is elongated, the pieces of the first n-type impurity diffusion layer ranging in number from one hundred to three hundred inclusive, each of the pieces of the elongated first n-type impurity diffusion layer having a width of between 50 μm and 150 μm inclusive, and
the seventh step forms elongated on-n-type-impurity-diffusion-layer grid electrodes as the on-n-type-impurity-diffusion-layer electrodes within regions of the pieces of the elongated first n-type impurity diffusion layer, the elongated on-n-type-impurity-diffusion-layer grid electrodes ranging in number from one hundred to three hundred inclusive.

22. The solar cell manufacturing method according to claim 16, wherein
a compound of the impurity element deposited on the second n-type impurity diffusion layer in the fourth step and the n-type dopant-containing paste are removed by etching at the same time in the fifth step.

23. The solar cell manufacturing method according to claim 16, wherein
the n-type impurity element is phosphorus.

24. The solar cell manufacturing method according to claim 16, wherein
after the first heat treatment in the third step is performed subsequent to the second step, the second heat treatment in the fourth step is performed in succession to the first heat treatment without the n-type silicon substrate being taken out of the processing chamber, or after the second heat treatment in the fourth step is performed subsequent to the second step, the first heat treatment in the third step is performed in succession to the second heat treatment without the n-type silicon substrate being taken out of the processing chamber.
